(19) United States
(12) Patent Application Publication
(10) Pub. No.: US 2024/0047116 A1
(43) Pub. Date: Feb. 8, 2024

(54) Printed Board Coil, High Frequency Transformer, and Electromagnetic Induction Heater

(71) Applicants: Hitachi, Ltd., Tokyo (JP); National University Corporation Hokkaido University, Sapporo-shi (JP)

(72) Inventors: Yuki KAWAGUCHI, Tokyo (JP); Hiroyuki SHOJI, Tokyo (JP); Koji ORIKAWA, Sapporo-shi (JP); Satoshi OGASAWARA, Sapporo-shi (JP); Naoki MURAKAMI, Sapporo-shi (JP)

(21) Appl. No.: 18/204,027

(22) Filed: May 31, 2023

(30) Foreign Application Priority Data
Aug. 8, 2022 (JP) 2022-126152

(51) Int. Cl. H01F 17/00; H01F 27/28; H05K 1/16

(52) U.S. Cl. CPC H01F 17/0013; H01F 27/2804; H05K 1/165; H05K 2201/086

(57) ABSTRACT

A printed board coil forms a coil with a plurality of turns, each formed by stacking a first layer having a first winding pattern and a second layer having a second winding pattern while having an insulation layer intervening therebetween. The first layers and the second layers are used for forming each of the coils. The coils are stacked having each of the insulation layers intervening between the coils by arranging the first layer and the second layer alternately in the stacking direction of the respective layers. The coils are connected in parallel to one another.

### CLAIM OF PRIORITY

The present application claims priority from Japanese Patent Application JP 2022-126152 filed on Aug. 8, 2022, the content of which is hereby incorporated by reference into this application.

### BACKGROUND OF THE INVENTION

The present invention relates to a printed board coil having each winding pattern of a planar conductor formed on a substrate, and a high frequency transformer, and an electromagnetic induction heater, each of which uses the printed board coil.

US2009/0085706A1 discloses the printed board coil which constitutes a spiral coil using a plurality of conductor patterns, each of which is formed by connecting a plate conductor (planar conductor) divided into multiple parts in a planar direction to a plate conductor of the other layer by way of a via or a through hole. Like the litz wire, the printed board coil disclosed in US2009/0085706A1 allows equalization of the current flowing through multiple plate conductors dividedly arranged in the planar direction to reduce high-frequency AC loss caused by the high-frequency magnetic field.

### SUMMARY OF THE INVENTION

The disclosed printed board coil ensures suppression of current concentration caused by the skin effect in the planar direction. In order to increase current capacity of the coil, it is essential to increase a cross-section area of the conductor by increasing the thickness of the plate conductor, or stacking multiple plate conductors to be arranged in parallel to one another. Increase in the plate conductor thickness causes increase in the high-frequency AC loss owing to the skin effect in the thickness direction. Meanwhile, if multiple plate conductors are stacked in parallel to one another, multiple patterns which are the same are arranged in parallel. The resultant proximity effect makes impedance between the conductor patterns unequal. Consequently, the circulating current is generated between the parallel arranged patterns, resulting in the increase in the high-frequency AC loss.

It is an object of the present invention to provide the printed board coil that ensures increase in the current capacity, and suppression of increase in the high frequency AC loss.

The object is attained by providing the printed board coil for forming a coil with a plurality of turns, each formed by stacking a first layer having a first winding pattern and a second layer having a second winding pattern while having an insulation layer intervening therebetween. The first layer and the second layer are used for forming each of the coils. The coils are stacked having each of the insulation layers intervening between the coils by arranging the first layer and the second layer alternately in a direction of stacking the first and the second layers. The coils are connected in parallel to one another.

The present invention allows increase in the current capacity of the printed board coil by parallel coil connection, and equalization of impedance through multiple winding patterns that constitute the coil in spite of the parallel coil connection. As a result, the present invention allows suppression of the circulating current to attain reduction in the high-frequency AC loss.

The problems, structures and effects except those described above are clarified by explanations of the following examples hereinafter.

### BRIEF DESCRIPTION OF THE DRAWINGS

FIG. 1 is an exploded view schematically illustrating a structure of a printed board coil of a first example (example 1) according to the present invention;

FIG. 2 is a plan view schematically illustrating a structure of a coil (first coil) constituting the printed board coil of the example 1;

FIG. 3 is an exploded plan view of a first layer and a second layer of the coil (first coil) as illustrated in FIG. 2;

FIG. 4 is a sectional view schematically illustrating the printed board coil of the example 1;

FIG. 5 is a sectional view schematically illustrating a structure for connecting lead wires of the printed board coil of the example 1;

FIG. 6 is a circuit diagram indicating application of the printed board coil of the example 1 to the high frequency transformer of an insulated DC/DC converter;

FIG. 7 is a sectional view schematically illustrating application of the printed board coil of the example 1 to the high frequency transformer of the insulated DC/DC converter;

FIG. 8 is an exploded view schematically illustrating a structure of a printed board coil as a comparative example of the printed board coil of the example 1;

FIG. 9 is a schematic sectional view of the printed board coil as illustrated in FIG. 8;

FIG. 10 is a sectional view schematically illustrating a printed board coil of an example 2, which has been applied to a heating coil for an IH cooking heater;

FIG. 11 is a plan view schematically illustrating the printed board coil of the example 2, which has been applied to the heating coil for the IH cooking heater;

FIG. 12A is a plan view schematically illustrating a structure of each winding pattern as the first layer and the third layer of the printed board coil of the second example (example 2) according to the present invention;

FIG. 12B is a plan view schematically illustrating a structure of each winding pattern as the second layer and the fourth layer of the printed board coil of the second example (example 2) according to the present invention;

FIG. 13 is an explanatory sectional view schematically illustrating the printed board coil of the example 2; and

FIG. 14 is an explanatory sectional view schematically illustrating the printed board coil of the example 2.

### DESCRIPTION OF THE PREFERRED EMBODIMENTS

The present invention relates to a printed board coil having a winding pattern of a planar conductor formed on the substrate, and a device using the printed board coil. The present invention will be described herein with respect to examples of the printed board coil, and devices exemplified by a high frequency transformer and an electromagnetic induction heater each as the device using the printed board coil according to the present invention. Arbitrary devices accommodate application of the printed board coil according to the present invention with no limitation to such devices as the high frequency transformer and the electromagnetic induction heater.

As the high frequency current at several tens kHz is supplied to windings used for the heating coil of the IH cooking heater or the high frequency transformer of the insulated DC/DC converter, high frequency AC loss occurs owing to the skin effect or the proximity effect under the influence of high frequency magnetic field. The winding of the heating coil and the high frequency transformer is formed by spirally winding the conductor. Accordingly, proximately arranged coils are mutually affected by the magnetic field strongly. In order to suppress the high frequency AC loss, the litz wire formed by stranding a plurality of insulated strands is used for the winding conductor. The coil to be manufactured using the litz wire requires such steps as stranding, winding, and terminal processing. The use of the litz wire for the coil causes the problem of difficulty in management of variation in electrical properties during mass production.

The process for forming the winding pattern on the printed board has been proposed for the purpose of suppressing variation in electrical properties. The use of the printed board eliminates the manufacturing step such as the stranding process. It is therefore possible to reduce variation in the electrical properties. Meanwhile, the use of simple planar conductor patterns to form the spiral coil concentrates the current flowing through the conductor pattern upon the center side of the coil. Consequently, it is more difficult to suppress the high frequency AC loss than the use of the litz wire coil.

The printed board coil of the example according to the present invention, which will be described below ensures equalization of the inter-layer impedance in spite of multi-layered conductor patterns in parallel arrangement. This allows reduction in the high frequency AC loss by suppressing the circulating current. This makes it possible to attain large current of the printed board coil with the multi-layered structure.

Examples according to the present invention will be described in detail referring to the drawings.

### EXAMPLE 1

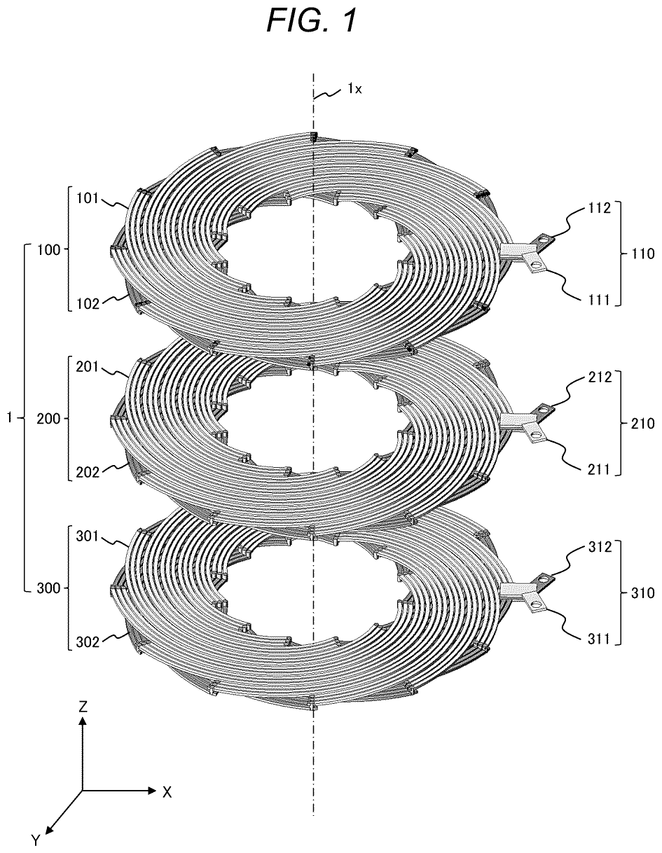

A first example (example 1) according to the present invention will be described referring to FIG. 1 to FIG. 9.

FIG. 1 is an exploded view schematically illustrating a structure of a printed board coil 1 of the first example (example 1) according to the present invention. In the example, six conductor layers are used for forming the printed board coil 1. X-axis, Y-axis, and Z-axis directions which are defined to be orthogonal to one another constitute three coordinate axes as illustrated in FIG. 1.

The printed board coil 1 of the example 1 includes a plurality of coils 100, 200, 300. In this example, three coils 100, 200, 300 constitute the printed board coil 1. However, the number of coils constituting the printed board coil 1 is not limited to three so long as the number is two or larger.

The coil (first coil) 100 includes a winding pattern 101, a winding pattern 102, a lead wire 111 led from the winding pattern 101, and a lead wire 112 led from the winding pattern 102. The lead wires 111 and 112 constitute a leader 110 of the coil 100. The coil (second coil) 200 includes a winding pattern 201, a winding pattern 202, a lead wire 211 led from the winding pattern 201, and a lead wire 212 led from the winding pattern 202. The lead wires 211 and 212 constitute a leader 210 of the coil 200. The coil (third coil) 300 includes a winding pattern 301, a winding pattern 302, a lead wire 311 led from the winding pattern 301, and a lead wire 312 led from the winding pattern 302. The lead wires 311 and 312 constitute a leader 310 of the coil 300.

In the example, the number of the winding pattern layers (conductors) constituting the printed board coil 1 is six. Each of the coils 100, 200, 300 is constituted by two-layered winding patterns.

Each of the coils 200, 300 is configured similarly to the coil 100. The following explanations will be made about the coil 100, and explanations about the coils 200 and 300 will be made with respect only to parts different from those of the coil 100.

The winding patterns 101 and 102 of the coil 100 are formed parallel to an X-Y plane. The Z-axis direction is defined as an up-down direction as illustrated in FIG. 1. The following explanations will be made by defining the up-down direction on the basis of FIG. 1. For example, the winding pattern 101 is formed as an upper layer with respect to the winding pattern 102. In other words, the winding pattern 102 is formed as the lower layer with respect to the winding pattern 101. The up-down direction as described above does not limit the up-down direction in the state where the printed board coil 1 is installed.

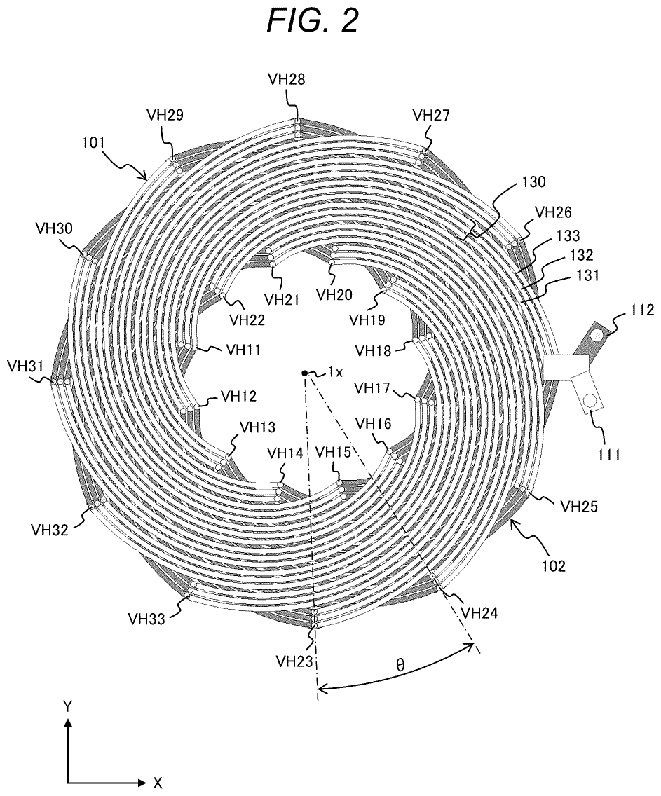

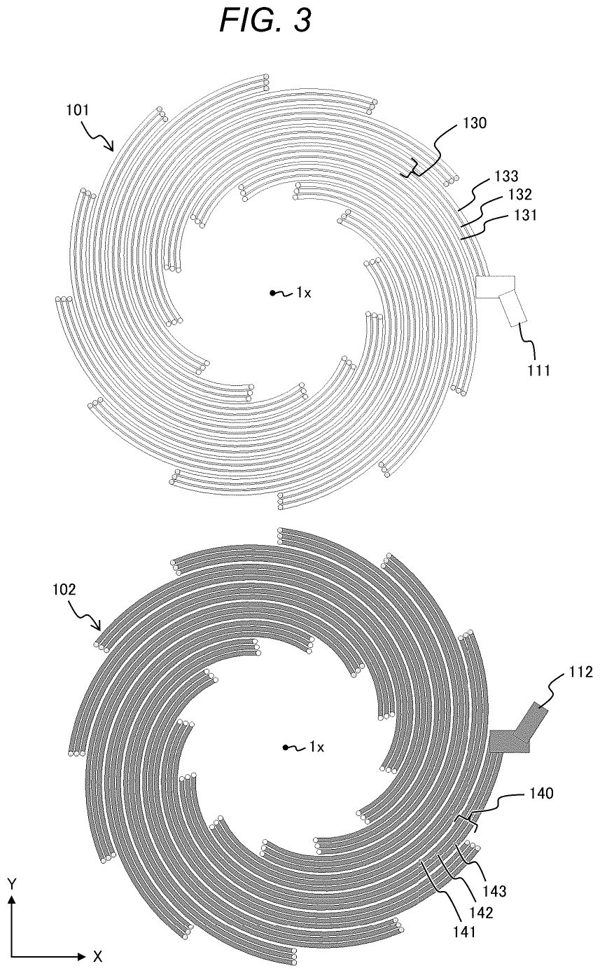

FIG. 2 is a plan view schematically illustrating a structure of the coil (first coil) 100 constituting the printed board coil 1 of the example 1. FIG. 3 is an exploded plan view of the coil (first coil) 100 as illustrated in FIG. 2, which is disassembled into a first layer (winding pattern 101) and a second layer (winding pattern 102).

The winding patterns 101, 102 are connected to an external circuit via the lead wires 111, 112 respectively led from one end of the pattern. Basically, the winding pattern 101 is composed of conductor patterns 130 each constituted by a plurality of planar patterns (divided windings) 131, 132, 133, each of which is curved and moves distant from a center axis 1x while turning therearound. In other words, the winding pattern 101 includes the conductor patterns 130 each constituted by the multiple planar patterns (divided windings) 131, 132, 133, each of which is curved and moves closer to the center axis 1x. The term “turn” herein includes the turn at the angle, which does not reach one cycle (360°).

Each of the winding patterns 101, 102 is constituted by multiple conductor patterns 130 each formed at every given turning angle θ with respect to the center axis 1x. End portions VH23, VH24 of two adjacent conductor patterns 130 are positioned on a circumference around the center axis 1x so that the end portions VH23, VH24 form a central angle θ. Other end portions VH11 to VH22, and VH25 to VH33 of the conductor patterns 130 are similarly positioned as described above.

The printed board coil 1 of the example has 12 conductor patterns 130 which are positioned while being circumferentially shifted at 30°. That is, the angle θ is set to 30°. The number of the conductor patterns 130 is not limited to 12, but may be set to the number except 12 so that the angle θ is set to be different from 30°.

The conductor pattern 130 of the printed board coil 1 of the example includes a plurality of radially divided planar patterns 131, 132, 133. In this example, the conductor pattern 130 of the printed board coil 1 is constituted by three divided planar patterns 131, 132, 133. However, the number of divided planar patterns is not limited to three. Preferably, for the purpose of reducing the high frequency AC loss under the skin effect, it is preferable to set the number of divided planar patterns 131, 132, 133 so that each width of those planar patterns 131, 132, 133 becomes twice or smaller than the skin depth which is determined by frequency of the current supplied to the coil 100. The skin depth d can be represented by the following formula.

d=√(2ρ/ων) (formula 1);

where ρ represents electric resistivity, ω represents angular frequency of the current flowing through the coil 100, and μ represents absolute magnetic permeability of the coil pattern. The angular frequency ω is represented by 2πf in which f is defined as frequency of the current flowing through the coil 100. When using copper for forming the coil pattern, the skin depth is 0.46 mm approximately at current frequency of 20 kHz. Accordingly, it is preferable to set each width of the planar patterns 131, 132, 133 to 0.9 mm or smaller, which is the value twice or smaller than the skin depth as an index.

The turning angle θ can be derived from the following formula 2.

θ=360/(N+1) (formula 2);

where N represents the number of coil turns, which may be a constant preliminarily given for designing the coil 100.

Basically, like the winding pattern 101, the winding pattern 102 is composed of conductor patterns 140 each constituted by a plurality of planar patterns (divided windings) 141, 142, 143, each of which is curved and moves distant from the center axis 1x while turning therearound. The winding pattern 102 includes the conductor patterns 140 each formed at a predetermined turning angle (central angle) θ with respect to the center axis 1x. The conductor pattern 140 of the printed board coil 1 of the example includes a plurality of radially divided planar patterns 141, 142, 143.

The winding pattern 102 is disposed at the position where the winding pattern 101 is turned at 180° in the Z-axis direction. As illustrated in FIG. 3, the conductor pattern 130 of the winding pattern 101 in a curved shape moves distant from the center axis 1x clockwise while turning therearound. Meanwhile, the conductor pattern 140 of the winding pattern 102 in a curved shape moves distant from the center axis 1x counterclockwise while turning therearound. That is, the winding patterns 101 and 102 are formed to make each turning direction opposite to each other when viewed from the same side in the Z-axis direction.

In the printed board coil 1 of the example, each of the first winding pattern 101 and the second winding pattern 102 includes a plurality of conductor patterns 130, 140, each of which is curved and moves distant from the center axis 1x while turning therearound. The second winding pattern 102 is in a position turned at 180° with respect to the first winding pattern 101 in the stacking direction (Z-axis direction).

All the conductor patterns 130, 140 which constitute the winding patterns 101, 102, respectively are symmetrically structured to allow equalization of magnetic flux which penetrates through the conductor patterns 130, 140. Similar to the use of the litz wire coil, it is expected to provide the effect for suppressing the high frequency AC loss under the proximity effect.

Although the drawing only illustrates the conductor patterns 130, 140 of the coil 100, the winding patterns 201, 202, 301, 302 of the coils 200, 300 are configured similarly to those illustrated in FIG. 3.

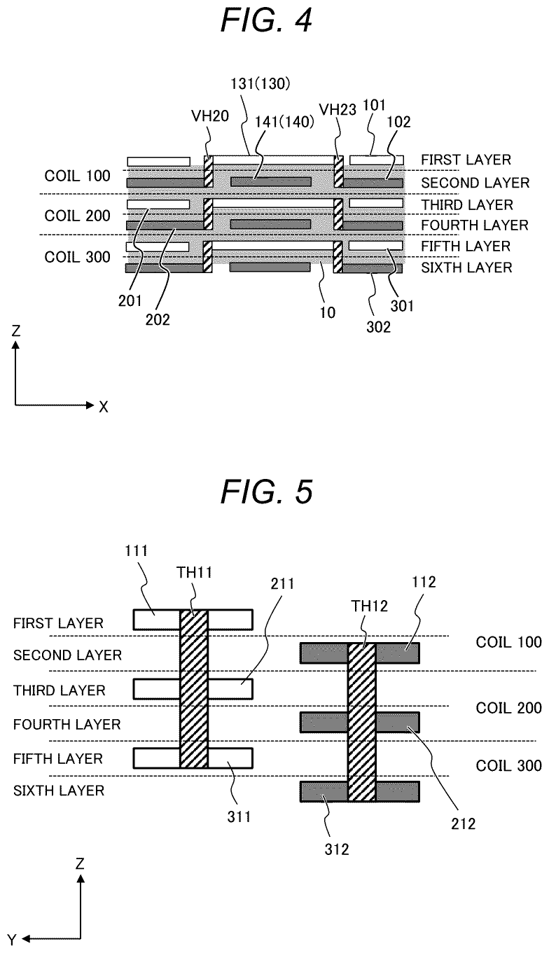

FIG. 4 is a sectional view schematically illustrating the printed board coil 1 of the example 1.

The winding pattern 101 of the coil (first coil) 100 constitutes the first layer of the printed board coil 1, and the winding pattern 102 constitutes the second layer of the printed board coil 1. The winding pattern 201 of the coil (second coil) 200 constitutes a third layer of the printed board coil 1, and the winding pattern 202 constitutes a fourth layer of the printed board coil 1. The winding pattern 301 of the coil (third coil) 300 constitutes a fifth layer of the printed board coil 1, and the winding pattern 302 constitutes a sixth layer of the printed board coil 1.

The first coil 100 includes the winding patterns 101 and 102. The winding patterns 101 and 102 are formed on one end surface (upper surface side) and the other end surface (lower surface side) of a substrate (insulation layer) 10, respectively. The winding patterns 101 and 102 are electrically insulated by the substrate 10 which intervenes therebetween.

The second coil 200 includes the winding patterns 201 and 202. The winding patterns 201 and 202 are formed on one end surface (upper surface side) and the other end surface (lower surface side) of the substrate 10, respectively. The winding patterns 201 and 202 are electrically insulated by the substrate 10 which intervenes therebetween.

The third coil 300 includes the winding patterns 301 and 302. The winding patterns 301 and 302 are formed on one end surface (upper surface side) and the other end surface (lower surface side) of the substrate 10, respectively. The winding patterns 301 and 302 are electrically insulated by the substrate 10 which intervenes therebetween.

The winding pattern 101 of the first coil 100 is formed on one end surface (upper end surface) of the substrate 10. The winding pattern 302 of the coil (third coil) 300 is formed on the other end surface (lower end surface) of the substrate 10. The first coil 100 and the second coil 200 are electrically insulated by the substrate 10 which intervenes therebetween. The second coil 200 and the third coil 300 are electrically insulated by the substrate 10 which intervenes therebetween. That is, the substrate 10 intervenes between the winding pattern 102 of the first coil 100 and the winding pattern 201 of the second coil 200. The substrate 10 intervenes between the winding pattern 202 of the second coil 200 and the winding pattern 301 of the third coil 300.

The first coil 100 composed of multiple turns is formed by electrically connecting the conductor patterns 130 (see FIG. 3) of the winding pattern 101 and the conductor patterns 140 (see FIG. 3) of the winding pattern 102 through vias VH11 to VH33 (see FIG. 2). Similar to the first coil 100, the conductor patterns with double-layered winding patterns of the second coil 200 and the third coil 300 are also electrically connected through vias VH11 to VH33.

In the embodiment, the vias VH11 to VH22 are positioned at radially inner ends (inner circumferential side) of the conductor patterns 130, 140 which constitute the winding patterns 101, 102, 201, 202, 301, 302, respectively. The vias VH23 to VH33 are positioned at radially outer ends (outer circumferential side) of the conductor patterns 130, 140 which constitute the winding patterns 101, 102, 201, 202, 301, 302, respectively. Lead wires 111, 112 are led from end portions at the radially outer sides (outer circumferential sides) of the conductor patterns 130, 140 which constitute the winding patterns 101, 102, 201, 202, 301, 302, respectively.

The winding patterns 201, 202 of the second coil 200, and the winding patterns 301, 302 of the third coil 300 are configured similarly to the winding patterns 101, 102 of the first coil 100. Consequently, it can be considered that the coils 100, 200, 300 are stacked having each of the insulation layers 10 intervening between the coils by arranging the first layers 101, 201, 301 of the first winding patterns, and the second layers 102, 202, 302 of the second winding patterns alternately in the stacking direction of the first and the second layers.

That is, the printed board coil 1 of the example is formed into a coil with a plurality of turns, each formed by stacking the first layer having the first winding pattern 101 and the second layer having the second winding pattern 102 while having the insulation layer 10 intervening therebetween. The first layers 101, 201, 301 and the second layers 102, 202, 302 are used for forming a plurality of coils 100, 200, 300. The coils 100, 200, 300 are stacked having each of the insulation layers 10 intervening therebetween by arranging the first layer 101, 201, 301 and the second layer 102, 202, 302 alternately in the direction of stacking the first and the second layers (Z-axis direction). The coils 100, 200, 300 are connected in parallel to one another.

FIG. 5 is a sectional view schematically illustrating a structure for connecting leaders 110 to 310 of the printed board coil of the example 1.

The coils 100, 200, 300 are connected in parallel at the leaders 110 to 310 via the through holes TH11, TH12, respectively (see FIG. 5). Specifically, the lead wire 111 of the first coil 100, the lead wire 211 of the second coil 200, and the lead wire 311 of the third coil 300 are connected via the through hole TH11. The lead wire 112 of the first coil 100, the lead wire 212 of the second coil 200, and the lead wire 312 of the third coil 300 are electrically connected via the through hole TH12.

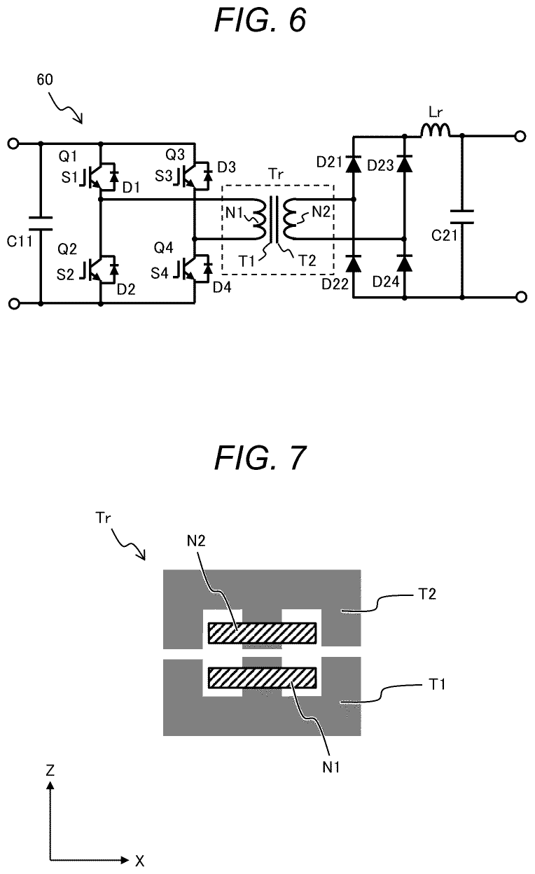

Referring to FIG. 6 and FIG. 7, explanations will be made with respect to application of the printed board coil 1 of the example 1 to a high frequency transformer Tr of an insulated DC/DC converter 60. FIG. 6 is a circuit diagram indicating application of the printed board coil 1 of the example 1 to the high frequency transformer Tr of the insulated DC/DC converter 60. FIG. 7 is a sectional view schematically illustrating application of the printed board coil 1 of the example 1 to the high frequency transformer Tr of the insulated DC/DC converter 60.

The insulated DC/DC converter includes a smoothing capacitor C11, a full-bridge circuit constituted by IGBTs Q1 to Q4, a high frequency transformer Tr, rectifier diodes D21 to D24, a smoothing reactor L4, and a smoothing capacitor C21. The high frequency transformer Tr includes a primary coil N1, a secondary coil N2, and magnetic cores T1, T2. The printed board coil 1 is used as the primary coil N1 and/or the secondary coil N2.

The high-frequency transformer Tr of the example includes the magnetic cores T1, T2, and the primary and the secondary coils N1, N2. The printed board coil 1 according to the above-described example is in the form of the primary coil N1 and/or the secondary coil N2.

The printed board coil 1 of the example is structured by forming multiple coils including the two-layer winding patterns each composed of upper and lower layers, that is, 101, 102, 201, 202, and 301, 302, respectively, and connecting the leaders 110 to 310 in parallel, each led from one end of the winding patterns. In the above-described structure, the same winding patterns are not arranged adjacently to each other. Accordingly, in the case where the winding patterns are arranged in parallel using the multi-layer substrate, impedance between the winding patterns can be equalized. The structure reduces influence under the proximity effect, which becomes problematic in parallel arrangement of the winding patterns, in other words, circulating current owing to difference in impedance between the winding patterns. Consequently, suppression of the high frequency AC loss is expected.

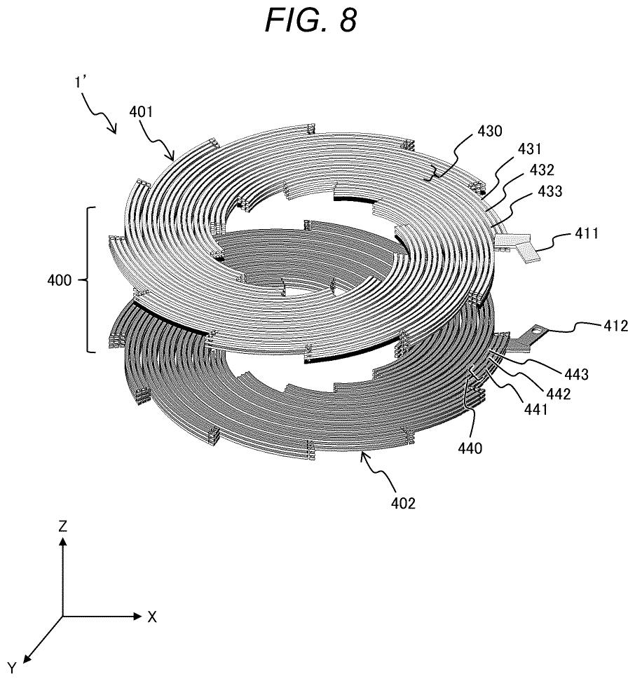

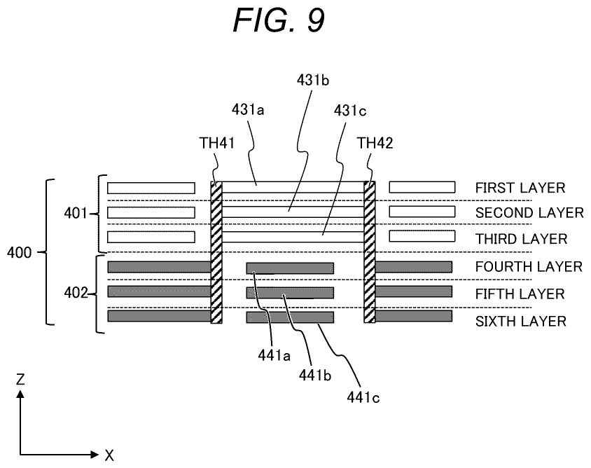

Referring to FIG. 8 and FIG. 9, a generally employed printed board coil 1′ will be described as a comparative example. FIG. 8 is an exploded view schematically illustrating a structure of the printed board coil 1′ as an example to be compared with the printed board coil 1 of the example 1. FIG. 9 is a schematic sectional view of the printed board coil 1′ as illustrated in FIG. 8.

Similar to the printed board coil 1 of the present example, the printed board coil 1′ includes six-layer substrate. A coil 400 of the printed board coil 1′ is composed of a winding pattern 401 and a winding pattern 402. Planar patterns 431 to 433 which constitute a conductor pattern 430 of the winding pattern 401 are formed similarly to the planar patterns which constitute the conductor pattern 130 (see FIG. 3) of the winding pattern 101 according to the example. Planar patterns 441 to 443 which constitute a conductor pattern 440 of the winding pattern 402 are formed similarly to the planar patterns which constitute the conductor pattern 140 (see FIG. 3) of the winding pattern 102 according to the example. A lead wire 411 is led from the winding pattern 401, and a lead wire 412 is led from the winding pattern 402.

Unlike the present example, in the comparative example, planar patterns 431a, 431b, 431c, which constitute the conductor pattern 430 of the winding pattern 401 are collectively arranged from the first to the third layer, respectively, and planar patterns 441a, 441b, 441c, which constitute the conductor pattern 440 of the winding pattern 402 are collectively arranged from the fourth to the sixth layer, respectively. The planar patterns 431a, 431b, 431c of the winding pattern 401 and the planar patterns 441a, 441b, 441c of the winding pattern 402 are electrically connected via through holes TH41, TH42 so that the planar patterns 431a, 431b, 431c, and the planar patterns 441a, 441b, 441c are arranged in the parallel relationship with one another.

For example, the planar patterns 431a, 431b, 431c of the structure according to the comparative example are not capable of keeping structural symmetry in the positional relationship of the respective patterns to the winding pattern 402 in the Z-axis direction (stacking direction). That is, each distance between the planar pattern 431a and the winding pattern 402, between the planar pattern 431b and the winding pattern 402, and between the planar pattern 431c and the winding pattern 402 in the Z-axis direction becomes different from one another. This may make the magnetic flux density penetrating through the respective planar patterns unequal. The resultant circulating current between the conductor patterns connected in parallel increases the high frequency AC loss to cause difficulty in obtaining the effect for increasing the conductor cross-sectional area, which is derived from the multilayered structure.

Referring to the coils 100, 200, 300 as illustrated in FIG. 4, in the example, the distance between the winding patterns 101 and 102 in the Z-axis direction is equalized. The distance between the planar patterns 130 and 140, which include the respective winding patterns 101, 102, 201, 202, 301, 302 is equalized. In the present example, the magnetic flux density penetrating through the respective planar patterns 130, 140 can be equalized.

### EXAMPLE 2

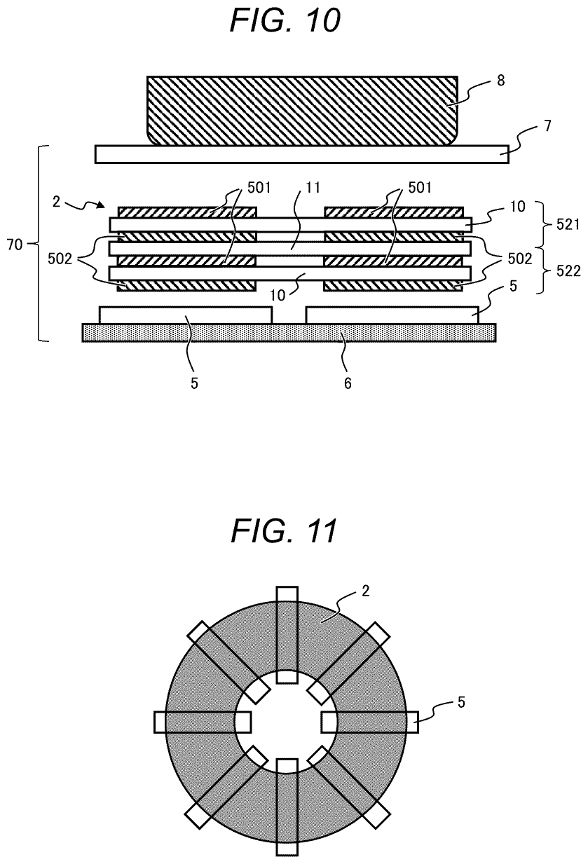

A second example (example 2) according to the present invention will be described referring to FIG. 10 to FIG. 14. The description which has been already explained in the example 1 will be omitted.

FIG. 10 is a sectional view schematically illustrating a printed board coil 2 of the example 2, which has been applied to a heating coil for an IH cooking heater. FIG. 11 is a plan view schematically illustrating the printed board coil 2 of the example 2, which has been applied to the heating coil for the IH cooking heater. FIG. 10 is a sectional view along the up-down direction. FIG. 11 illustrates the state where a top plate 7 and a pan 8 have been removed from the view illustrated in FIG. 10.

Coils 521 and 522 include substrates (insulation layers) winding patterns 501 each formed on one surfaces of the respective substrates 10, and winding patterns 502 each formed on the other surfaces of the respective substrates 10. The coils 521 and 522 are stacked while having a substrate (insulation layer) 11 intervening therebetween to form the printed board coil 2. A material formed by impregnating a phenol resin or an epoxy resin in paper or a glass cloth is used for forming the substrate 11. The IH cooking heater (electromagnetic induction heater) 70 includes the top plate 7 on which the pan 8 as a cooker is placed. The printed board coil 2 for heating the pan 8 is disposed below the top plate 7. The printed board coil 2 is disposed above an upper surface of a ferrite core 5 serving as a magnetic path of the magnetic flux generated by the printed board coil 2. The pan 8 placed on the upper surface of the top plate 7 is induction-heated by the magnetic flux generated by the printed board coil 2. The printed board coil 2 and the ferrite cores 5 are supported with a support member 6. As FIG. 11 illustrates, the ferrite cores 5 are radially arranged around the center of the printed board coil 2.

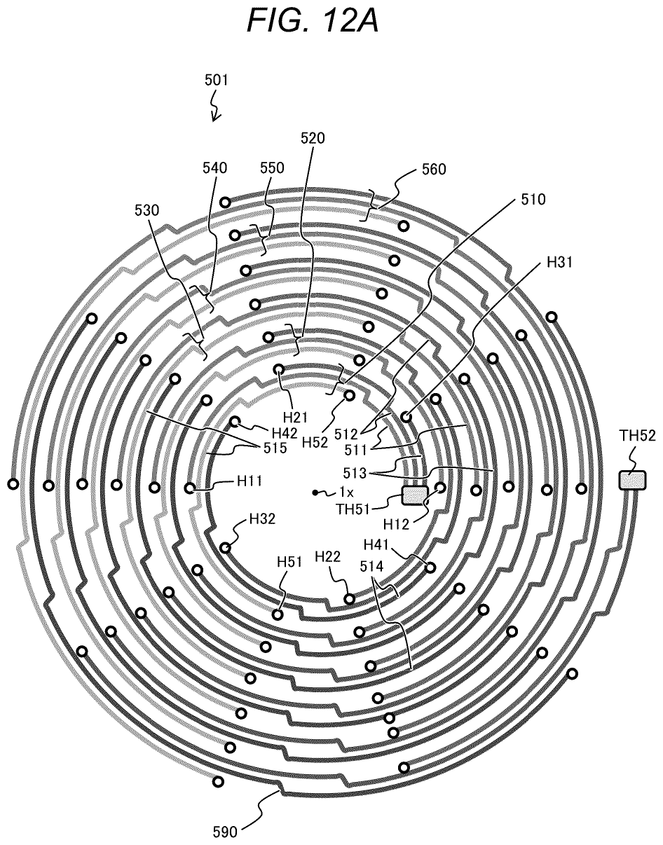

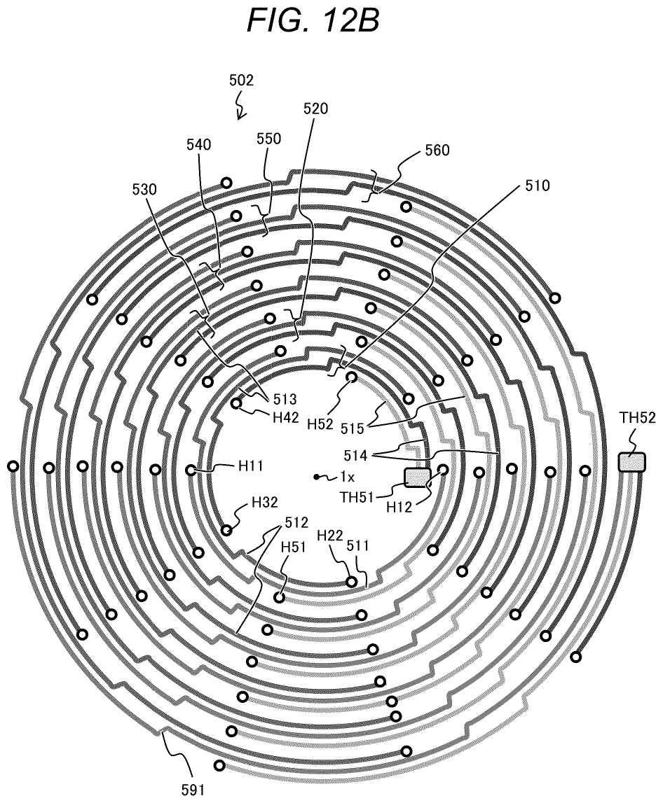

The electromagnetic induction heater 70 of the example includes the top plate 7 on which the pan 8 is placed, and the coil disposed below the top plate 7 for heating the pan 8 placed on the top plate 7. Each of the printed board coils 521, 522 is in the form of the printed board coil as described referring to FIG. 12A and FIG. 12B.

FIG. 12A is a plan view schematically illustrating a structure of each of the winding patterns 501 as the first layer and the third layer of the printed board coil 2 of the second example (example 2) according to the present invention. FIG. 12B is a plan view schematically illustrating a structure of each of the winding patterns 502 as the second layer and the fourth layer of the printed board coil of the second example (example 2) according to the present invention.

The printed board coil 2 is formed using the winding patterns 501, 502 each spirally wound through multiple turns. Each of the winding patterns 501, 502 is of six-turn type including coil turns 510 to 560. The coil turn 510 constitutes an innermost circumferential turn, and the coil turn 560 constitutes an outermost circumferential turn. Each of the coil turns 510 to 560 is composed of five radially divided conductor patterns 511 to 515. The conductor patterns 511 to 515 are formed into the coil by connecting multiple planar conductors dividedly arranged in multiple layers using through holes (for example, H11, H12 as illustrated in FIG. 12A and FIG. 12B) while having the substrate 10 intervening therebetween.

The conductor patterns 511 to 515 are distinguished by radial arrays of the through holes H11 to H52. The respective sets of through holes H11 to H52 are arranged to form radial arrays. For example, there are six radially arranged through holes H11. There are five radially arranged through holes H12 (seven, inclusive of TH51, TH52). One of the conductor patterns 511, which is disposed on the innermost circumference is formed between the through hole TH51 and the through hole H12 adjacent to the through hole TH51 at the radially outer side. The conductor pattern 511 which is disposed at the outer circumferential side is formed between the two radially adjacent through holes H12.

A stranding structure will be described in detail by taking the coil turn (first coil turn) 510 as an example.

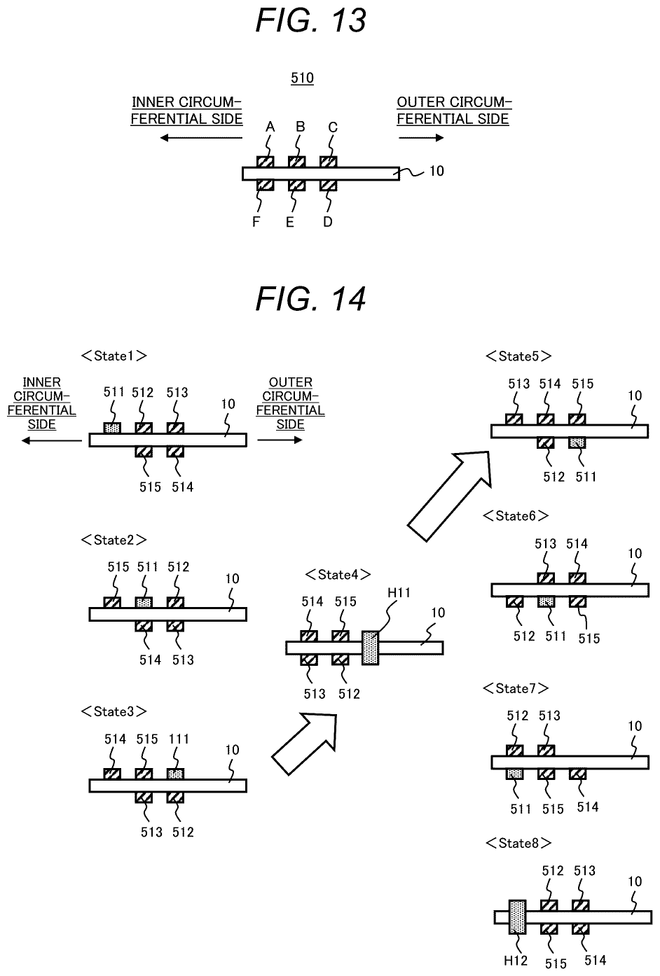

FIG. 13 is an explanatory sectional view schematically illustrating the printed board coil of the example 2. FIG. 14 is an explanatory sectional view schematically illustrating the printed board coil of the example 2.

As FIG. 12A and FIG. 12B illustrate, the first coil turn 510 of the example 2 has the conductor patterns 511 to 516 circumferentially formed dividedly. The coil is formed by connecting conductor patterns applied on one and the other surfaces of the substrate 10 dividedly via the through holes H11 to H52.

As FIG. 13 illustrates, positions of the conductor patterns constituting the first coil turn 510 are defined as lanes A, B, and C from the innermost circumferential side to the outer circumferential side on the upper surface of the substrate 10, and defined as lanes D, E, and F from the outermost circumferential side to the inner circumferential side on the lower surface side of the substrate 10.

Referring to FIG. 14 in addition to FIG. 12A and FIG. 12B, transitional states of the conductor patterns constituting the first coil turn 510 will be described while focusing on the conductor pattern 511.

### <State 1 to State 3>

The conductor pattern 511 makes a transition from the lane A as a starting point at the innermost circumferential side in a sequential order toward the outer circumferential side at every predetermined angle θ1 from the center axis of the coil pattern 501. That is, the conductor pattern 511 proceeds to the lane B in State 2, and to the lane C in State 3.

When the conductor pattern 511 reaches the lane C at the outermost circumferential side, it proceeds to State 4. The predetermined angle (central angle) θ1 is determined in reference to the formula 3. The term Nstd in the formula 3 represents the number of divided sections of the conductor pattern.

θ1 =180/Nstd (formula 3)

### <State 4>

The conductor pattern 511 is positioned on the lane C at the outermost circumferential side, and connected to the lane

D on the other surface via the through hole H11.

### <State 5 to State 8>

The conductor pattern 511 makes a transition from the lane D on the other surface as the starting point to the next lane in a sequential order toward the inner circumferential side at every predetermined angle θ1. That is, the conductor pattern 511 proceeds to the lane E in State 6, and then to the lane F in State 7.

When the conductor pattern 511 reaches the lane F, it is connected to the coil turn (second coil turn) 520 via the through hole H12.

In the printed board coil 2 of the example, each of the winding patterns 501, 502 includes a plurality of coil turns 510 to 560 each of which moves distant from the center axis 1x while turning therearound. The coil turns 510 to 560 include a plurality of conductor patterns 511 to 515 divided in a radial direction of the coil. The conductor patterns 511 to 515 make transitions toward an outer circumferential side at every predetermined central angle θ1.

Each of the conductor patterns 511 to 515 of the winding pattern 501 includes a transition section 590 which makes a transition toward the outer circumferential side at every predetermined central angle θ1. Each of the conductor patterns 511 to 515 of the winding pattern 502 includes a transition section 591 which makes a transition toward the inner circumferential side at every predetermined central angle θ1.

The above-described structure applies to each of the conductor patterns 512 to 515, and accordingly, detailed explanations thereof will be omitted. Each of the conductor patterns 512 to 515 makes a transition to the next lane in a sequential order toward the outer circumferential side. When the pattern reaches the lane C, it is connected to the lane D on the other surface via the through hole H21, H31, H41, H51. The pattern further makes a transition to the next lane in a sequential order toward the inner circumferential side. After the pattern reaches the lane F, it is connected to the coil turn (second coil turn) 120 via the through hole H22, H32, H42, H52.

The printed board coil 2 of the example 2 employs the stranding structure for the coil turn forming conductor patterns so that positions of the conductor patterns are exchanged successively between the inner circumferential side and the outer circumferential side at every predetermined angle. This makes it possible to equalize the impedance. Compared with the printed board coil of the example 1, the printed board coil of the example 2 is allowed to easily equalize the impedance between the conductor patterns even if the coil is formed into an ellipse or a quadrilateral rather than the concentric circle.

The present invention is not limited to the examples as described above, but includes various modifications. For example, the examples are described in detail for readily understanding of the present invention which is not necessarily limited to the one equipped with all structures as described above. It is possible to replace a part of the structure of one example with the structure of another embodiment. The one example may be provided with an additional structure of another example. It is further possible to add, remove, and replace the other structure to, from and with a part of the structure of the respective examples.

### LIST OF REFERENCE SIGNS

1 . . . printed board coil, 1x . . . center axis, 7 . . . top plate, 10 . . . insulation layer (substrate), 70 . . . electromagnetic induction heater, 100 . . . coil (first coil), 101 . . . first winding pattern (first layer), 102 . . . second winding pattern (second layer), 130 . . . conductor pattern, 131, 132, 133 . . . planar pattern, 140 . . . conductor pattern, 141, 142, 143 . . . planar pattern, 200 . . . coil (second coil), 300 . . . coil (third coil), 501, 502 . . . winding pattern, 510 to 560 . . . coil turn, 511 to 515 . . . conductor pattern, 521, 522 . . . coil, N1 . . . primary coil, N2 . . . secondary coil, T1 ,T2 . . . magnetic core, Tr . . . high frequency transformer, θ1 . . . central angle

1. A printed board coil for forming a coil with a plurality of turns, each formed by stacking a first layer having a first winding pattern and a second layer having a second winding pattern, an insulation layer intervening between the first and the second layers, wherein:
the first layer and the second layer are used for forming each of the coils;
the coils are stacked having each of the insulation layers intervening between the coils by arranging the first layer and the second layer alternately in a direction of stacking the first and the second layers; and
the coils are connected in parallel to one another.

2. The printed board coil according to claim 1, wherein:
each of the first winding pattern and the second winding pattern includes a plurality of conductor patterns, each of which is curved and moves distant from a center axis while turning around the center axis; and
the second winding pattern is in a position turned at 180° with respect to the first winding pattern in the stacking direction.

3. The printed board coil according to claim 2, wherein the conductor pattern includes a plurality of radially divided planar patterns.

4. The printed board coil according to claim 1, wherein:
each of the first winding pattern and the second winding pattern includes a plurality of coil turns each of which moves distant from a center axis while turning around the center axis;
the coil turns include a plurality of conductor patterns divided in a radial direction of the coil; and
the conductor patterns make transitions toward an outer circumferential side at every predetermined central angle θ.

5. A high frequency transformer including a magnetic core, a primary coil, and a secondary coil, wherein the printed board coil according to claim 1 is in the form of the primary coil and/or the secondary coil.

6. An electromagnetic induction heater including a top plate on which a pan is placed, and a coil disposed below the top plate for heating the pan placed on the top plate, wherein the printed board coil according to claim 1 is in the form of the coil.
